(19) United States
(12) Patent Application Publication
(10) Pub. No.: US 2024/0023204 A1
(43) Pub. Date: Jan. 18, 2024

(54) COATED CONDUCTOR FOR HEATER EMBEDDED IN CERAMIC

(71) Applicant: Lam Research Corporation, Fremont, CA (US)

(72) Inventors: Joel Hollingsworth, Portland, OR (US); Ramkishan Rao Lingampalli, Danville, CA (US); Pankaj Hazarika, Sherwood, OR (US)

(21) Appl. No.: 18/246,849

(22) PCT Filed: Sep. 28, 2021
(86) PCT No.: PCT/US2021/052473

§ 371 Date: Mar. 27, 2023

Related U.S. Application Data
(60) Provisional application No. 63/198,109, filed on Sep. 29, 2020.

(51) Int. Cl. H05B 3/28; C04B 35/64

(52) U.S. Cl. CPC H05B 3/283; C04B 35/64; C04B 2235/3217; C04B 2235/3225; C04B 2235/386; H05B 2203/017

(57) ABSTRACT

Various embodiments herein relate to techniques for fabricating a platen for use in a semiconductor processing apparatus, as well as the platens and intermediate structures produced by such techniques. For example, such techniques may include depositing a coating on a heater to form a coated heater, where the heater includes a metal wire on which the coating is formed; placing the coated heater in powder; consolidating the powder into a cohesive mass to form a powder-based composite; and sintering the powder-based composite to form the platen, where the platen includes the heater embedded in sintered ceramic material. The coating on the heater may act to protect the heater from chemical attack from carbon- and/or oxygen-containing compounds that may be present during sintering. The platen may be part of a pedestal that, once fabricated, may be installed in a semiconductor processing apparatus.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor device fabrication involves a number of different processes performed in various semiconductor processing apparatuses. These processes can include, e.g., lithography, deposition, etching, etc. A semiconductor substrate is typically supported on a pedestal or other type of substrate support during these fabrication processes. In some cases, the pedestal includes an embedded heater that can be used to heat the substrate during processing.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods, apparatus, and systems for fabricating a platen for use in a semiconductor processing apparatus, as well as the platens and intermediate structures produced by such methods, apparatus, and systems. Generally, the techniques described herein involve coating a heater before the heater is embedded in ceramic material in a sintering operation. The coating protects the heater during the sintering operation, thus preventing chemical attack of the heater during sintering and producing a platen with improved uniformity.

In one aspect of the disclosed embodiments, a method of fabricating a platen for use in a semiconductor processing apparatus is provided, the method including: depositing or otherwise forming a coating on a heater to form a coated heater, where the heater includes a metal wire on which the coating is formed; placing the coated heater in powder; consolidating the powder into a cohesive mass to form a green body or a powder-based composite; and sintering the green body or a powder-based composite to form the platen, where the platen includes the heater embedded in sintered ceramic material. The terms green body and powder-based composite may be used interchangeably herein.

Various deposition methods may be used to form the coating. In some embodiments, the coating is deposited on the heater using atomic layer deposition. In some embodiments, the coating is deposited on the heater using chemical vapor deposition. In some embodiments, the coating is deposited on the heater using electroplating. In some embodiments, the coating is deposited on the heater using electroless plating. In some embodiments, coating is deposited on the heater using dip coating. In some embodiments, the coating is deposited on the heater using thermal spraying. In some embodiments, the coating is deposited on the heater using plasma spraying. In some embodiments, the coating is deposited on the heater using physical vapor deposition. In various embodiments, the coating is deposited to a thickness of at least about 5 Å.

A number of different materials and combinations of materials can be used for the coating. For instance, in various embodiments, the coating includes a metal. In some such cases, the coating may include a metal oxide. In some cases, the coating includes at least one material selected from the group consisting of calcium oxide, magnesium oxide, yttrium oxide, and lanthanum oxide. In other embodiments, the coating is an elemental metal. In some embodiments, the coating includes a metal nitride. In some embodiments, the coating includes an intermetallic compound.

In some implementations, the coating is a sacrificial coating that includes a sacrificial material, where carbon- and/or oxygen-containing components present during sintering are more reactive with the sacrificial material than they are with the metal wire of the heater. In some such cases, the metal wire is molybdenum and the coating is tungsten.

In some implementations, the coating is a barrier coating that includes a barrier material, where carbon- and/or oxygen-containing components present during sintering are less reactive with the barrier material than they are with the metal wire of the heater. In some such cases, the coating includes boron nitride. In some cases, the barrier material is substantially non-reactive with the carbon- and/or oxygen-containing components present during sintering.

In some embodiments, the coating survives sintering such that the platen includes the coated heater embedded in the sintered ceramic material. In other embodiments, the coating is substantially consumed or diffuses away from the heater during sintering.

In some cases, the coating can include two or more layers having different compositions. In some embodiments, the layers are deposited through atomic layer deposition, with layers of a first composition alternating with layers of a second composition. In some cases, depositing or otherwise forming the coating on the heater includes depositing alternating layers of aluminum oxide and yttrium oxide on the heater through atomic layer deposition.

In some embodiments, depositing or otherwise forming the coating includes forming a conversion coating. The conversion coating may be formed from the heater itself, or from an intermediate coating.

In another aspect of the disclosed embodiments, a platen for use in a semiconductor processing apparatus is provided, where the platen is fabricated according to any of the methods claimed or otherwise described herein.

In another aspect of the disclosed embodiments, a platen for use in a semiconductor processing apparatus is provided, the platen including: a coated heater including a metal wire with a coating thereon; and a sintered ceramic material, where the coated heater is embedded in the sintered ceramic material.

In some embodiments, the coating has a thickness of at least about 5 Å. In these or other embodiments, the wire metal may have a diameter between about 0.002-0.05 inches.

A number of different materials may be used for the coating. In some embodiments, the coating includes a metal. In some such cases, the coating includes a metal oxide, a metal nitride, an intermetallic compound, and/or an elemental metal. In a particular example the coating includes boron nitride.

In another aspect of the disclosed embodiments, a platen for use in a semiconductor processing apparatus is provided, the platen including: a heater including a metal wire, where the metal wire does not have carbide particles embedded therein; and a sintered ceramic material, where the heater is embedded in the sintered ceramic material.

In another aspect of the disclosed embodiments, a green body or a powder-based composite for use as a platen in a semiconductor processing apparatus is provided, the green body or a powder-based composite including: a coated heater including a metal wire with a coating thereon; an unsintered ceramic material, where the coated heater is embedded in the unsintered ceramic material.

In some embodiments, the coating has a thickness of at least about 5 Å. In these or other embodiments, the metal wire may have a diameter between about 0.002-0.05 inches.

A number of materials and combinations of materials may be used for the coating. In some embodiments, the coating includes a metal. In some such cases, the coating includes a metal oxide. The metal oxide may include at least one material selected from the group consisting of calcium oxide, magnesium oxide, yttrium oxide, and lanthanum oxide. In some embodiments, the coating includes an elemental metal.

In some implementations, the coating is a sacrificial coating including a sacrificial material, and carbon- and/or oxygen-containing components present during a sintering operation are more reactive with the sacrificial material than they are with the metal wire. In some such cases, the metal wire is molybdenum and the coating is tungsten.

In some implementations, the coating is a barrier coating including a barrier material, and carbon- and/or oxygen-containing components present during a sintering operation are less reactive with the barrier material than they are with the metal wire of the heater. In some such cases, the coating includes boron nitride. In these or other embodiments, the barrier material may be substantially non-reactive with the carbon- and/or oxygen-containing components present during the sintering operation.

These and other features of the disclosed embodiments will be described in detail below with reference to the associated drawings.

### BRIEF DESCRIPTION OF DRAWINGS

FIG. 1 presents an illustration of a heater in a platen of a pedestal.

FIG. 2 presents a flow chart describing a method of fabricating a platen.

FIG. 3 presents a flow chart describing a method of fabricating a platen, including a step of coating a heater, according to various embodiments herein.

FIGS. 4 and 5 are diagrams of example processing apparatus for performing methods in accordance with certain disclosed embodiments, particularly where the coating is applied through atomic layer deposition or chemical vapor deposition.

FIGS. 6 and 7 are diagrams of example processing apparatus for performing methods in accordance with certain disclosed embodiments, particularly where the coating is applied through electroplating.

FIG. 8 is a diagram of an example processing apparatus for performing methods in accordance with certain disclosed embodiments, particularly where the coating is applied through dip coating.

FIG. 9 is a diagram of an example processing apparatus for performing methods in accordance with certain disclosed embodiments, particularly where the coating is applied through plasma spraying.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor substrates, often referred to as wafers, are subjected to many different processes over the course of manufacturing semiconductor devices. In many cases, the substrates are supported on a substrate support such as a pedestal during these manufacturing processes. Various embodiments herein relate to techniques for producing pedestals that have improved properties such as more uniform heating performance.

The pedestal may provide a variety of functions and benefits during processing. For example, the pedestal provides a degree of uniformity and repeatability by ensuring that the substrates are positioned at a repeatable location within a processing apparatus. In some cases, the pedestal provides hardware for securing the substrate onto the pedestal, for example through electrostatic forces in the case of an electrostatic chuck (ESC). Such hardware may include one or more electrostatic chuck electrodes that act to clamp the substrate onto the pedestal. In some cases, the pedestal includes hardware for generating plasma in the processing apparatus. Such hardware may include, e.g., one or more RF electrodes, which may be implemented as a wire mesh in some cases. In various cases, the pedestal provides hardware for controlling the temperature of the substrate during processing. Such hardware can include heaters, coolers, heat transfer conduits, etc. In many cases, the pedestal includes one or more embedded heaters. The heater(s) may provide one or more independent zones for temperature control. Unfortunately, the heaters are not always able to provide a desired temperature profile on the substrate, for example due to chemical reactions that can occur during fabrication of the pedestals.

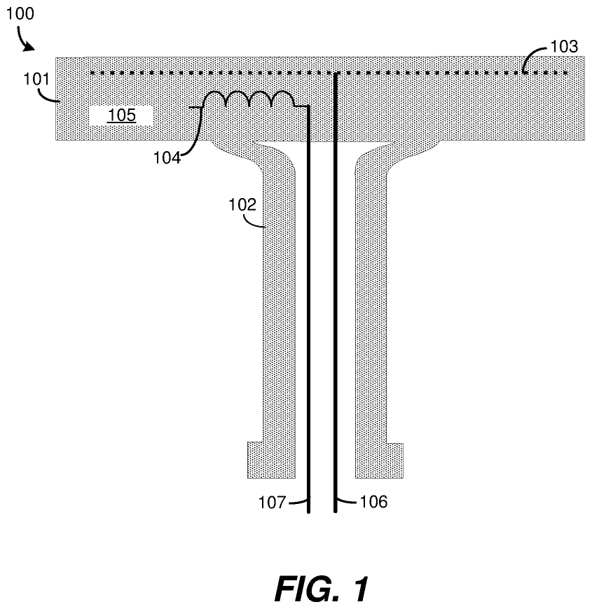

FIG. 1 depicts a cross-sectional view of a pedestal 100. In this example, pedestal 100 includes platen 101 and stem 102. The platen 101 includes various hardware therein, including electrode 103, which acts as both an RF electrode and an ESC electrode. In a particular embodiment, electrode 103 is implemented as a wire mesh. The wire mesh may be made of a refractory metal (e.g., a metal with a particularly high melting point) such as molybdenum, tungsten, niobium, rhenium, tantalum, chromium, hafnium, iridium, osmium, rhodium, ruthenium, titanium, vanadium, zirconium, or a combination thereof. Such materials are particularly useful in cases where the pedestal 100 will be subjected to high processing temperatures. Platen 101 also includes heater 104. In this example, heater 104 is a drawn wire that is coiled into a helix and then wound into a desired pattern within platen 101. The heater 104 may be made of a refractory metal such as those listed above. Example thicknesses for the wire that forms heater 104 may be between about 0.002-0.05 inches. While only a single heater 104 is shown, it is understood that one or more heaters 104 may be present throughout the platen 101. The heaters 104 may be independently controllable to provide a desired temperature profile on the substrate. The desired temperature profile is often a uniform temperature profile, though non-uniform temperature profiles may be useful in some cases. In order to achieve a desired temperature profile, the heater 104 is designed to have a particular resistance and length at each position, thereby enabling the heater 104 to provide a desired amount of joule heating power to each portion of the platen 101 and any substrate thereon. The body 105 of platen 101 is made of aluminum nitride, which provides high thermal conductivity. The electrode 103 and heater 104 are embedded in the aluminum nitride body 105 of platen 101.

The stem 102 also includes some hardware. For example, connection lines 106 and 107 provide electrical connection to electrode 103 and heater 104, respectively. The connection lines 106 and 107 may be positioned in a hollow center portion of stem 102, as shown in FIG. 1. Additional connection lines (not shown) may be provided in cases where multiple electrodes 103 and/or heaters 104 are used, or where the platen 101 includes additional hardware. The stem 102 serves as a mechanical support for platen 101. Further, the stem 102 provides a hermetic seal (e.g., via an O-ring on the end opposite platen 101) and a thermal break between the platen 101 and the remaining portions of the processing apparatus.

The techniques described herein are applicable to substrate supports such as the one shown in FIG. 1, as well as some alternative substrate supports. For example, the techniques herein are not limited to cases where the substrate support includes a stem. Generally, the embodiments herein involve coating one or more heater before the heater is embedded into a substrate support. As such, the embodiments herein are useful in cases where the heater is capable of being coated, such as heater 104 in FIG. 1. By contrast, in some substrate supports the heater is implemented as a paste that is silk screened into a desired pattern. Such paste-based silk-screened heaters cannot be coated in the same way.

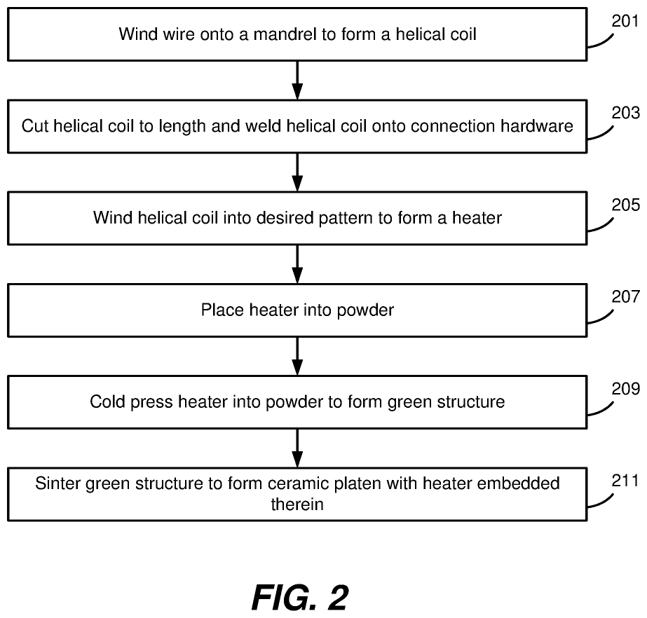

FIG. 2 presents a flow chart describing a method of manufacturing a platen of a pedestal such as the one shown in FIG. 1. Certain manufacturing problems that can arise are discussed in the context of FIG. 2. The method of FIG. 2 begins with operation 201, where wire is wound onto a mandrel, forming a helical coil. As mentioned above, the wire may be a refractory metal such as molybdenum or tungsten. Next, at operation 203, the helical coil is cut to length and welded onto connection hardware. One or more helical coils may be provided as desired for a particular application, for example to provide multiple heaters. At operation 205, the helical coil is wound into a desired pattern, forming the heater.

Next, at operation 207, the heater and any other components that are to be embedded in the platen (e.g., see electrode 103 of FIG. 1) are placed into a die and surrounded with powder. The powder includes aluminum nitride and a sintering aid. The most common type of sintering aid sits between various crystal grains of the ceramic (e.g., aluminum nitride) and frustrates the tendency of the ceramic grains to grow into larger crystals. Limiting crystal grain size increases the speed at which sintering is completed. In other words, the sintering aid allows the sintering process to proceed more quickly. The sintering aid also acts to draw out dissolved oxygen from the aluminum nitride. Dissolved oxygen makes aluminum nitride less thermally conductive, increasing the risk of thermal shock (which is a common failure mode for pedestals). By drawing out the dissolved oxygen and increasing the thermal conductivity of the aluminum nitride, it decreases the risk that the pedestal will break due to thermal expansion when power is supplied to the heater. In some cases, the sintering aid includes an oxide of a rare earth element such as yttrium or lanthanum. In some cases, the sintering aid includes an oxide of an alkaline earth metal (e.g., group 2 metal) such as calcium, magnesium, etc. or of a rare earth metal, such as yttrium, lanthanum, etc. Example materials that may be used for the sintering aid include, but are not limited to, calcium oxide (e.g., CaO), magnesium oxide (e.g., MgO), yttrium oxide (e.g., Y₂O₃), lanthanum oxide (e.g., La₂O₃), and combinations thereof. The sintering aid may be provided at a concentration of about 5-10% (by weight) of the powder. The remaining 90-95% (by weight) of the powder is the aluminum nitride.

At operation 209, the heater and powder (and any other components placed in the powder) are cold pressed together, forming a composite referred to as a green body or a powder-based composite (e.g., a cohesive ceramic structure prior to sintering). The terms green body and powder-based composite are used interchangeably. Example pressures for the cold pressing in operation 209 may be between about 100 MPa-1000 MPa, example temperatures may be between about 0-60° C., and example cold pressing durations may be between about 10 seconds-5 minutes. At operation 211, the green structure is sintered to form the platen with the heater (and other components) embedded therein. Example sintering temperatures may be between about 1750-1850° C. During the sintering process, the porosity of the platen is substantially reduced, and gas pathways within the body of the platen are substantially cut off. The high temperature and pressure of sintering act to crush all of the air/empty space out of the platen, thereby forming a dense ceramic material in which the heater (and other components) are embedded.

Unfortunately, the sintering process in operation 211 changes the resistivity of the heater in a non-uniform manner, thereby producing variations in resistivity at different portions of the heater. These variations in resistivity are problematic because they can result in uneven substrate heating when the heater/platen is used to heat a substrate during processing. In many cases, the variations are seen as center-to-edge variations, with degraded resistivity (e.g., greater resistivity) near the edges of the platen compared to the center of the platen; however, these variations are not always repeatable, and there is significant variation not only within a single platen, but among the different platens that are produced by a given die or set of dies.

Without wishing to be bound by theory or mechanism of action, it is believed that the metal of the heater is reacting with carbon and/or oxygen during the sintering process. The oxygen may be present in the atmosphere in which sintering takes place. The carbon may originate from the die used for sintering. For example, in many cases the die is made of a graphite fiber composite material that is held together with pyrolytic carbon, also referred to as carbon-carbon composite. The die material is semi-porous and picks up moisture at room temperature. During sintering, the moisture reacts with the carbon, producing carbon-containing compounds that diffuse through the platen and attack the heater, especially near the edges of the platen. The carbon-containing compounds may include carbides and/or oxycarbides. In some cases, the carbon-containing compounds may include carbon monoxide, methane, etc.

Diffusion of the carbon-containing compounds through the platen causes formation of carbide materials on certain portions of the metal heater. Portions of the heater that are closer to the outer surfaces of the platen are more likely to be affected due to the lower diffusion distance (as compared with portions of the heater that are closer to the center of the platen). Areas where the carbide materials form on the heater exhibit degraded resistivity. As mentioned above, the changes in resistivity seen during sintering are not uniform. For example, in addition to center-to-edge variations, there are also seasonal variations. The resistivity changes are most substantial when there is a high degree of humidity.

The inventors have discovered that in order to reduce or even prevent such chemical attacks and related resistivity changes, the heater can be coated before it is placed into the powder. Various different types of coatings may be used, as described further below. The coating acts to protect the heater during the sintering process, thereby preventing or reducing formation of carbide and/or oxycarbide materials on the surface of the heater.

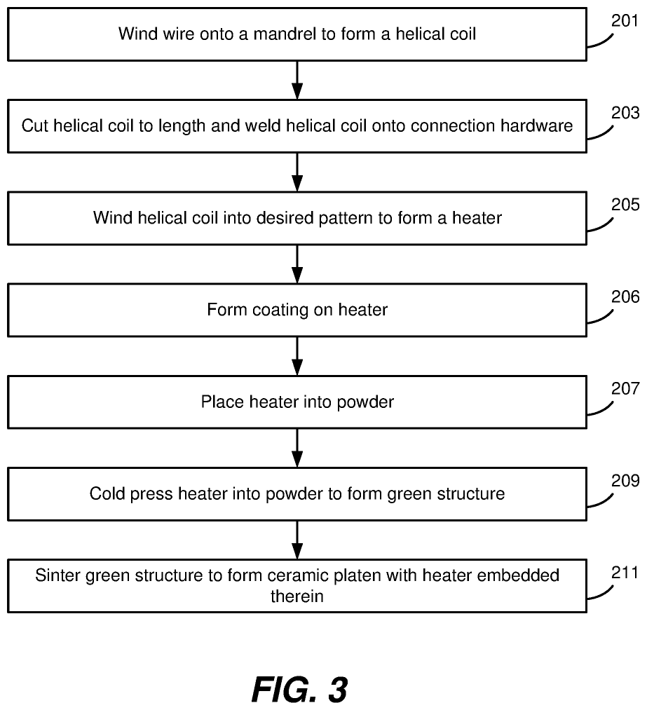

FIG. 3 presents a flow chart describing a method of manufacturing a substrate support (or a portion thereof), according to various embodiments herein. For example, the method may be used to manufacture the platen 101 of pedestal 100 shown in FIG. 1. The method of FIG. 3 is similar to the method of FIG. 2, and only the differences will be described. Any details provided with respect to FIG. 2 may also apply to the method of FIG. 3. In addition to the steps described in FIG. 2, the method of FIG. 3 includes operation 206, where a coating is formed on the heater. This coating operation may be done after the heater is formed/shaped in operation 205, and before the heater is placed into the powder at operation 207. The coating operation may also be performed at an earlier time in cases where the coating is able to withstand being shaped. In certain embodiments, a molybdenum-based wire is coated with tantalum and/or tungsten before being wound to form the heater. In some such cases, an elevated temperature may be provided as the coated wire is wound to form the heater. In various embodiments, the coating may have a minimum thickness of at least about 5 angstroms. In these or other embodiments, the coating may have a maximum thickness of about 100 angstroms or less, for example about 50 angstroms or less, or about 10 angstroms or less. The coating may be conformal in many cases.

In one embodiment, the coating is made of one or more substances similar to those used as sintering aids suitable for use with the encapsulating ceramic material. Such coatings are often referred to herein as sintering aid coatings. The material used in the coating may be the same composition as, or a different composition than, the sintering aid used in the powder. Example sintering aid materials are listed above. Example deposition methods are described further below. The sintering aid coating may provide a temporary physical barrier between the heater and its surroundings to reduce or prevent carbon- and/or oxygen-containing elements or compounds from attacking the heater trace during at least an initial portion of the sintering process.

Much like the powdered form of the sintering aid, it is expected that some or all of a coating with composition similar to a sintering aid would diffuse away from the heater over the course of the sintering process. As the coating material diffuses away from the heater, it provides less protection against chemical degradation of the heater. Generally, the slower and less completely the coating material diffuses away from the heater, the greater the degree of protection the sintering aid coating provides during sintering. This protection may be balanced with other factors. For example, one advantage of diffusing the coating material away from the heater during sintering is that the sintering aid coating is not present in the fabricated platen/pedestal, and therefore does not act as a thermal barrier that could otherwise compromise the efficiency at which the heater transfers heat to a substrate during processing. As another example, if the coating ceases to protect the metal during the second stage of sintering, the closure of continuous gas passages through the ceramic body during the first stage of sintering will have reduced the rate of material transport from the furnace environment to the metal surface, e.g., ceramic encapsulation will perform some or all of the function of the coating by that stage of processing. The stages of sintering are described in Sintering Crystalline Solids. I. Intermediate and Final State Diffusion Models. Journal of Applied Physics, 32, 787 (1961), which is herein incorporated by reference in its entirety.

In a particular example, the sintering aid coating and the sintering aid powder are both yttrium oxide. During sintering, the yttrium oxide sintering aid coating diffuses into the surrounding yttrium oxide/aluminum nitride.

In another embodiment, the coating is made of a reactive material that acts as a sacrificial coating. The sacrificial coating may be more reactive to the carbon- and/or oxygen-containing elements or compounds compared to the material of the heater (e.g., a tantalum or zirconium coating might be more reactive than a molybdenum or tungsten heater wire, etc.). In this way, the carbon- and/or oxygen-containing elements or compounds that would otherwise attack the heater during sintering instead preferentially attack the material of the sacrificial coating. The sacrificial coating may be wholly or partially consumed over the course of the sintering process. Much like the sintering aid coating, the sacrificial coating provides the greatest protection against chemical attack of the heater during the initial portion of the sintering process, while the coating is fully intact. The sacrificial coating provides less protection as it is consumed over the course of sintering. In cases where the sacrificial coating is completely consumed during sintering, the sacrificial coating is not present in the finished platen/pedestal, and therefore cannot act as a thermal barrier. In cases where the sacrificial coating is not completely consumed during sintering, some sacrificial coating may remain on the heater in the fabricated platen/pedestal. Depending on the material of the sacrificial coating, any remaining coating may act as a thermal barrier.

Generally, the material of the sacrificial coating should be selected such that the carbon- and/or oxygen-containing compounds that attack the heater during sintering are more reactive with the material of the sacrificial coating than they are with the material of the heater itself. In various embodiments, the sacrificial coating is made of a material that has a lower (e.g., more negative) enthalpy of formation for forming a carbide material, as compared to the enthalpy of formation for forming a carbide material from the material of the heater. Ibis ensures that the carbon- and/or oxygen-containing compounds preferentially react with the sacrificial coating rather than the heater itself. For instance, when the heater is made of molybdenum, the sacrificial coating may be made of a material that has a lower enthalpy of formation for forming a carbide material as compared to the enthalpy of forming molybdenum carbide from molybdenum. Similarly, when the heater is made of tungsten, the sacrificial coating may be made of a material that has a lower enthalpy of formation for forming a carbide material as compared to the enthalpy of forming tungsten carbide from tungsten. In various embodiments, the sacrificial coating may be made of a material that has a melting point that is higher than the temperature used to sinter. In other embodiments, the sacrificial coating may comprise a material that has a melting point that is lower than the temperature used to sinter. In such embodiments, it is preferred that the liquid so formed (e.g., the liquid being formed as a result of the coating melting at high sintering temperatures) have a low wetting angle upon contact with the heater surface, to maintain coverage; it is also preferred that the liquid have a high wetting angle upon contact with each powder constituent present, to reduce absorption of the coating by the powder. If necessary, a refractory metal coating can be applied to the heater as an under-coat, to provide more-favorable wetting conditions for the sacrificial coating.

In various examples, the sacrificial coating may include a material selected from the group consisting of: light metals such as aluminum metal, titanium metal, or magnesium metal; intermetallic compounds that include one or more light metals, such as nickel aluminide, titanium aluminide, magnesium silicide, etc.; Group IV refractory metals, such as zirconium or hafnium; and miscellaneous transition metals with a strong affinity for carbon, such as chromium, niobium, and tungsten. Because the sacrificial coating is designed to be more reactive than the heater, it should be a different material than the heater itself. In one particular embodiment, the heater is molybdenum and the sacrificial coating is tungsten.

In another embodiment, the coating is made of a material that is highly resistant to attack from carbon- and/or oxygen-containing elements or compounds that would otherwise attack the heater itself. This type of coating may be referred to as a barrier coating, and it provides a physical barrier between the heater and the species that would attack and degrade the heater. Because the barrier coating is resistant to attack, it is substantially not reacted/consumed during the sintering process. Further, the barrier coating may be made of a material that substantially does not diffuse away from the heater during sintering. As a result, the barrier coating may provide superior protection against chemical attack on the heater during sintering, as compared to the sintering aid coating or the sacrificial coating.

Because the barrier coating may not be removed/consumed/diffused away during sintering, it may remain on the heater after the sintering process is complete. Depending on the material of the barrier coating, the barrier coating may act as a thermal barrier between the heater and the surrounding ceramic material when the pedestal is used to process substrates.

The material selected for the barrier coating should be relatively resistant to reactions with the carbon- and/or oxygen-containing compounds that would otherwise attack the heater during sintering. In various embodiments, the material of the barrier coating has a higher enthalpy of formation for forming carbide materials, as compared to the enthalpy of formation for forming a carbide from the material of the heater. For example, where the heater is made of molybdenum, it may be coated with a barrier coating made of a material that has a higher enthalpy of formation for forming carbides, as compared to the enthalpy of formation for forming molybdenum carbide from molybdenum. Similarly, where the heater is made of tungsten, it may be coated with a barrier coating made of a material that has a higher enthalpy of formation for forming carbides, as compared to the enthalpy of formation for forming tungsten carbide from tungsten. The material selected for the barrier coating may have a melting point that is higher than the sintering temperature. In other embodiments, the material selected for the barrier coating may have a melting point that is lower than the sintering temperature.

Example materials for the barrier coating include, but are not limited to, precious metals such as platinum, palladium, ruthenium, or rhodium; nitride compounds such as aluminum nitride or boron nitride; oxides with high melting point and low vapor pressure, such as zirconium oxide, yttrium aluminate, magnesium aluminate, etc. Because the barrier coating is designed to be less reactive than the heater, it should be a different material than the heater itself.

In various embodiments, the coating (e.g., which may be a sintering aid coating, a sacrificial coating, or a barrier coating) that is applied to the heater does not affect the thermal conductance from the heater to the encapsulating ceramic. In these or other embodiments, the coating applied to the heater does not directly affect the electrical resistance of the heater circuit. In other embodiments, the coating may affect the thermal and/or electrical performance of the system. In some cases, the coating may advantageously increase the thermal conductance from the heater to the surrounding ceramic material. In some such cases, the coating may materially increase the thermal conductance from the heater to the surrounding ceramic material. A boron nitride coating may be one example of a material that materially increases thermal conductance. In other embodiments, the coating may decrease the thermal conductance from the heater to the surrounding ceramic material. In various cases, this decrease may be limited to about 20% or less.

A number of different deposition techniques are available for forming the coating on the heater before the heater is embedded in ceramic. For instance, in various embodiments the coating may be formed through atomic layer deposition, chemical vapor deposition, physical vapor deposition, plating, dip coating, thermal spraying, plasma spraying, conversion coating, or a combination thereof. Other coating techniques may be used as desired for a particular application. During deposition of the coating, the heater is treated as a substrate (e.g., an object being worked upon). The coating is typically formed in a reaction chamber that is separate from the reaction chamber in which the coated heater/platen/pedestal will be installed/used to process semiconductor substrates.

In some cases, the coating is provided through atomic layer deposition. The uncoated heater is provided to a reaction chamber. A first reactant is delivered to the reaction chamber and allowed to adsorb onto the surface of the heater. The reaction chamber may then be purged and/or evacuated to remove unadsorbed first reactant. Next, a second reactant is delivered to the reaction chamber and reacts with the first reactant on the surface of the heater, thereby forming the coating on the heater. In some cases, the reaction is driven by thermal energy (e.g., thermal ALD), and in other cases, the reaction is driven by plasma energy (e.g., plasma enhanced ALD). After the reaction, the reaction chamber may again be purged and/or evacuated to remove unadsorbed reactants and reaction byproducts. These dosing, reacting, and purging steps can be repeated until the coating reaches its final thickness.

In many embodiments herein, the coating includes metal (e.g., an elemental metal, a metal oxide, etc.). As such, at least one reactant used to form the coating may be a metal-containing reactant. In some embodiments, for example where the coating includes a metal oxide, the first reactant may be a metal-containing reactant and the second reactant may be an oxygen-containing reactant.

In various embodiments, the coating may be formed by depositing alternating layers of two or more materials, each of which is deposited in a separate ALD cycle. For instance, in some cases the coating includes layers of aluminum oxide alternating with layers of yttrium oxide (or other sintering aid materials, or other coating materials mentioned herein). The coating may include more layers of aluminum oxide, more layers of yttrium oxide, or substantially equal numbers of these layers. This type of aluminum-yttrium-oxide material has previously been used to form films that are resistant to fluoridation. Such materials are further discussed in PCT Publication No. WO2020/023302, and in PCT Publication No. WO2020/123082, each of which is incorporated by reference herein in its entirety. Such materials have not previously been used to coat a wire (e.g., a heater) before it is embedded in ceramic (e.g., a ceramic platen of a pedestal).

In some embodiments, the coating may be provided through chemical vapor deposition. In this case, the uncoated heater is provided to a reaction chamber and two or more gas phase reactants are simultaneously delivered to the reaction chamber. The reactants react with one another in gas phase and deposit a reaction product (e.g., the coating) on the heater. The reaction may be driven by thermal energy (e.g., thermal CVD) or plasma energy (e.g., plasma enhanced CVD).

In some embodiments, the coating may be provided through plating. The plating may be electroplating or electroless plating. Where plating is used, the uncoated heater is provided to a reaction chamber having an electrolyte therein. The electrolyte includes cations of a metal that is to be deposited on the heater. The electrolyte may include additional species as desired for a particular application. The heater is immersed in the electrolyte, and a reduction reaction occurs to reduce the metal cations and deposit the metal on the surface of the heater. Where electroplating is used, the reduction reaction is driven by means of a direct electrical current, with the heater acting as the cathode of an electrolytic cell. Where electroless plating is used, the reaction is driven by means of a chemical reducing agent in the electrolyte.

In some embodiments, the coating may be provided through dip coating. Where dip coating is used, the uncoated heater is provided to a reaction chamber having a bath therein. The heater is immersed into the bath, which includes a mixture of the coating material in a solvent. The mixture deposits on the heater as the heater is pulled out of the bath. Excess mixture is allowed to drain from the surface of the heater, and then the solvent is evaporated from the mixture to form the coating on the heater.

In some embodiments, the coating may be provided through thermal spraying or plasma spraying. Plasma spraying is a type of thermal spraying. Where thermal spraying is used, the uncoated heater is provided to a reaction chamber and sprayed with heated coating material. For example, the coating material may be heated (in some cases melted) by electrical means (e.g., plasma or arc) or chemical means (e.g., combustion flame), and then accelerated toward the heater in the form of micrometer-size particles. The coating material feedstock is typically provided as a powder or a wire (or in some cases as a liquid suspension), and it may be melted to a molten or semi-molten form. Where plasma spraying is used, the coating material feedstock may be melted in a plasma jet emanating from a plasma torch, which propels the molten coating material toward the heater to be coated.

In some embodiments, the coating may comprise a conversion coating, formed from the material of the heater conductor itself or from some intermediate coating. Carburization, nitridation, and anodization are examples of conversion coating processes. Any of the coatings described herein may be used as an intermediate coating from which a conversion coating is formed. In certain embodiments, the heater wire or an intermediate coating on the heater wire is exposed to controlled amounts of carbon under conditions that form a uniform and protective coating layer. In certain embodiments, the coating may include a sacrificial coating with a barrier coating grown from the sacrificial coating. In other words, a sacrificial coating may be provided and then converted into a barrier coating. As a specific example, the sacrificial coating may be aluminum (or an aluminum-containing intermetallic material), which may be converted into a barrier coating through anodization, controlled surface nitridation (or other nitridation process), etc. In another example, the sacrificial coating may be titanium, which may be converted into a barrier coating through anodization, nitridation, etc. In certain embodiments, a barrier coating may be formed by a reaction (e.g., a complete reaction) of a metal coating and a reactant (e.g., an oxygen-containing reactant, nitrogen-containing reactant, carbon-containing reactant, etc.). In a particular example, the metal coating is yttrium, which is then exposed to an oxidizing environment to produce a yttrium oxide coating.

In some embodiments, the coating may be provided via physical vapor deposition, such as via sputtering or thermal evaporation.

Generally speaking, appropriate processing conditions for forming the coating may be selected by those of ordinary skill in the art.

The techniques described herein can be used to form platens with improved uniformity compared to previous manufacturing methods. For example, the content of non-metal phases in heater wires will be reduced in average magnitude and (more importantly) in variability, both when comparing center-to-edge within each heater, and when comparing one heater to another. Thermal uniformity of the platen at the relevant operating temperature should improve. Further, the heater resistance should show less variability within the population of heaters. These factors combine to provide substantially improved heater uniformity and substrate processing uniformity.

### Apparatus

The techniques described herein may be performed by any appropriate apparatus or collection of apparatuses. An appropriate apparatus includes hardware for performing the methods described herein, and a controller configured to cause such methods. As mentioned above, a number of different techniques are available for forming the coating on the heater. The apparatus used to form the coating will depend on the coating technique that is used. Some example apparatuses are discussed below. Such apparatuses may be paired with one or more additional apparatus for performing any one or more of the operations described in relation to FIG. 2 or 3. In a particular embodiment, the additional apparatus may include a press for performing the cold press in operation 209 and/or for performing the sintering in operation 211.

Further, once the heater is coated and embedded in ceramic to form the platen/pedestal, the platen/pedestal may be installed in a semiconductor processing apparatus. The platen/pedestal may be used in a wide variety of semiconductor processing apparatuses, including but not limited to deposition apparatuses, etching apparatuses, plasma treatment apparatuses, ion implantation apparatuses, etc. Generally, such platens/pedestals may be useful in various contexts where a substrate is supported and heated during processing.

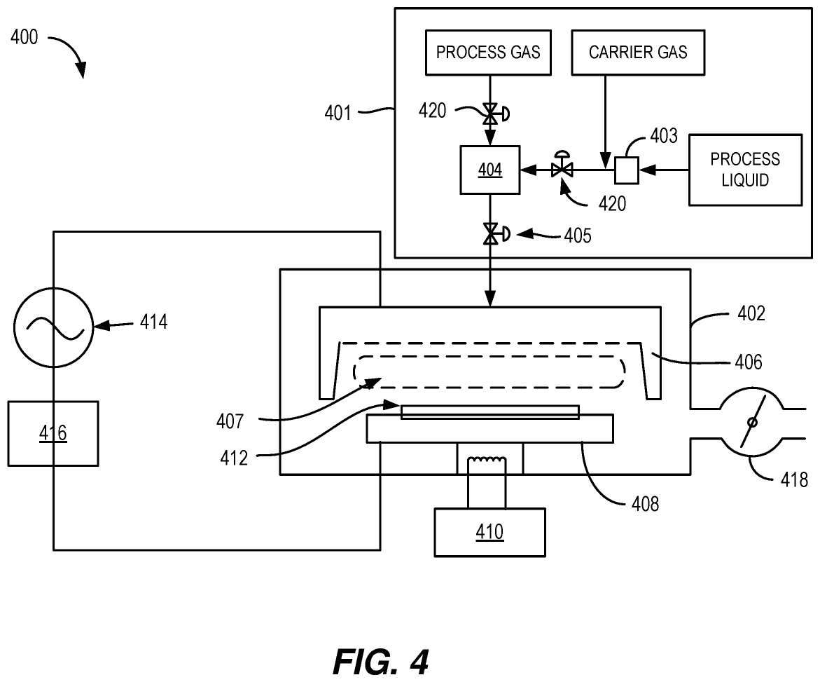

FIG. 4 schematically shows an embodiment of a process station 400 that may be used to deposit material (such as the heater coating described herein) using atomic layer deposition (ALD) and/or chemical vapor deposition (CVD), either of which may be plasma enhanced. For simplicity, the process station 400 is depicted as a standalone process station having a process chamber body 402 for maintaining a low-pressure environment. However, it will be appreciated that a plurality of process stations 400 may be included in a common process tool environment. Further, it will be appreciated that, in some embodiments, one or more hardware parameters of process station 400, including those discussed in detail below, may be adjusted programmatically by one or more computer controllers.

Process station 400 fluidly communicates with reactant delivery system 401 for delivering process gases to a distribution showerhead 406. Reactant delivery system 401 includes a mixing vessel 404 for blending and/or conditioning process gases for delivery to showerhead 406. One or more mixing vessel inlet valves 420 may control introduction of process gases to mixing vessel 404. Similarly, a showerhead inlet valve 405 may control introduction of process gasses to the showerhead 406.

Some reactants may be stored in liquid form prior to vaporization at and subsequent delivery to the process station. For example, the embodiment of FIG. 4 includes a vaporization point 403 for vaporizing liquid reactant to be supplied to mixing vessel 404. In some embodiments, vaporization point 403 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 403 may be heat traced. In some examples, mixing vessel 404 may also be heat traced. In one non-limiting example, piping downstream of vaporization point 403 has an increasing temperature profile extending from approximately 100° C. to approximately 150° C. at mixing vessel 404.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 403. In one scenario, a liquid injector may be mounted directly to mixing vessel 404. In another scenario, a liquid injector may be mounted directly to showerhead 406.

In some embodiments, a liquid flow controller upstream of vaporization point 403 may be provided for controlling a mass flow of liquid for vaporization and delivery to process station 400. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 406 distributes process gases toward substrate 412 (e.g., in this case the substrate 412 may be the heater being coated). In the embodiment shown in FIG. 4, substrate 412 is located beneath showerhead 406, and is shown resting on a pedestal 408. It will be appreciated that showerhead 406 may have any suitable shape, and may have any suitable number and arrangement of ports for distributing processes gases to substrate 412.

In some embodiments, a microvolume 407 is located beneath showerhead 406. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 408 may be raised or lowered to expose substrate 412 to microvolume 407 and/or to vary a volume of microvolume 407. For example, in a substrate transfer phase, pedestal 408 may be lowered to allow substrate 412 to be loaded onto pedestal 408. During a deposition process phase, pedestal 408 may be raised to position substrate 412 within microvolume 407. In some embodiments, microvolume 407 may completely enclose substrate 412 as well as a portion of pedestal 408 to create a region of high flow impedance during a deposition process.

Optionally, pedestal 408 may be lowered and/or raised during portions the deposition process to modulate process pressure, reactant concentration, etc., within microvolume 407. In one scenario where process chamber body 402 remains at a base pressure during the deposition process, lowering pedestal 408 may allow microvolume 407 to be evacuated. Example ratios of microvolume to process chamber volume include, but are not limited to, volume ratios between 1:400 and 1:10. It will be appreciated that, in some embodiments, pedestal height may be adjusted programmatically by a suitable computer controller.

In another scenario, adjusting a height of pedestal 408 may allow a plasma density to be varied during plasma activation and/or treatment cycles included in the deposition process. At the conclusion of the deposition process phase, pedestal 408 may be lowered during another substrate transfer phase to allow removal of substrate 412 from pedestal 408.

While the example microvolume variations described herein refer to a height-adjustable pedestal, it will be appreciated that, in some embodiments, a position of showerhead 406 may be adjusted relative to pedestal 408 to vary a volume of microvolume 407. Further, it will be appreciated that a vertical position of pedestal 408 and/or showerhead 406 may be varied by any suitable mechanism within the scope of the present disclosure. In some embodiments, pedestal 408 may include a rotational axis for rotating an orientation of substrate 412. It will be appreciated that, in some embodiments, one or more of these example adjustments may be performed programmatically by one or more suitable computer controllers.

Returning to the embodiment shown in FIG. 4, showerhead 406 and pedestal 408 electrically communicate with RF power supply 414 and matching network 416 for powering a plasma. In some embodiments, the plasma energy may be controlled by controlling one or more of a process station pressure, a gas concentration, an RF source power, an RF source frequency, and a plasma power pulse timing. For example, RF power supply 414 and matching network 416 may be operated at any suitable power to form a plasma having a desired composition of radical species. Examples of suitable powers are included above. Likewise, RF power supply 414 may provide RF power of any suitable frequency. In some embodiments, RF power supply 414 may be configured to control high- and low-frequency RF power sources independently of one another. Example low-frequency RF frequencies may include, but are not limited to, frequencies between 50 kHz and 400 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 408 may be temperature controlled via heater 410.

Heater 410 may be fabricated using the methods described herein. Further, in some embodiments, pressure control for deposition process station 400 may be provided by butterfly valve 418. As shown in the embodiment of FIG. 4, butterfly valve 418 throttles a vacuum provided by a downstream vacuum pump (not shown). However, in some embodiments, pressure control of process station 400 may also be adjusted by varying a flow rate of one or more gases introduced to process station 400.

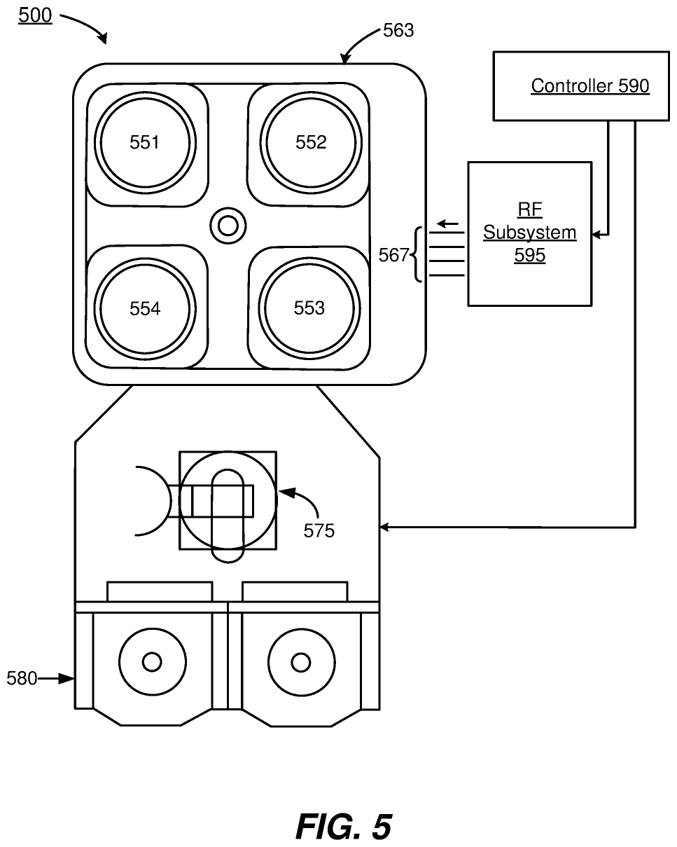

It may be appreciated that a plurality of process stations may be included in a multi-station processing tool environment, such as shown in FIG. 5, which depicts a schematic view of an embodiment of a multi-station processing tool. Processing apparatus 500 employs chamber 563 that includes multiple fabrication process stations, each of which may be used to perform processing operations on a substrate held in a substrate holder, such as a pedestal, at a particular process station. In the embodiment of FIG. 5, the chamber 563 is shown having four process stations 551, 552, 553, and 554. Other similar multi-station processing apparatuses may have more or fewer process stations depending on the implementation and, for example, a desired level of parallel processing, size/space constraints, cost constraints, etc. Also shown in FIG. 5 is substrate handler robot 575, which may operate under the control of system controller 590, configured to move substrates from loading port 580 and into chamber 563, and onto one of process stations 551, 552, 553, and 554.

FIG. 5 also depicts an embodiment of a system controller 590 employed to control process conditions and hardware states of processing apparatus 500. System controller 590 may include one or more memory devices, one or more mass storage devices, and one or more processors, as described herein.

RF subsystem 595 may generate and convey RF power to chamber 563 via radio frequency input ports 567. In particular embodiments, chamber 563 may comprise input ports in addition to radio frequency input ports 567 (additional input ports not shown in FIG. 5). Accordingly, chamber 563 may utilize 8 RF input ports. In particular embodiments, process stations 551-554 of chamber 165 may each utilize first and second input ports in which a first input port may convey a signal having a first frequency and in which a second input port may convey a signal having a second frequency. Use of dual frequencies may bring about enhanced plasma characteristics.

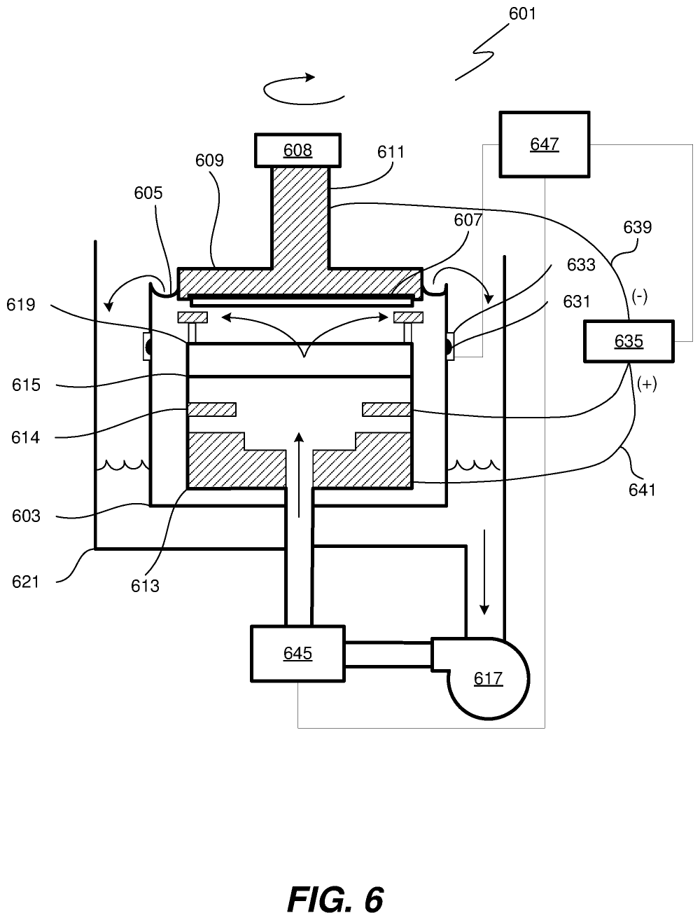

FIG. 6 presents an example of an electroplating cell in which electroplating may occur, for example to form the coating on the heater. Often, an electroplating apparatus includes one or more electroplating cells in which the substrates (e.g., in this case the substrate is the heater being coated) are processed. Only one electroplating cell is shown in FIG. 6 to preserve clarity. In some cases, as here, anodic and cathodic regions of the plating cell are separated by a membrane so that plating solutions of different composition may be used in each region. Plating solution in the cathodic region is called catholyte; and in the anodic region, anolyte. A number of engineering designs can be used in order to introduce anolyte and catholyte into the plating apparatus.

Referring to FIG. 6, a diagrammatical cross-sectional view of an electroplating apparatus 601 in accordance with one embodiment is shown. The plating bath 603 contains the plating solution, which is shown at a level 605. The catholyte portion of this vessel is adapted for receiving substrates in a catholyte. A substrate 607 (e.g., a heater to be coated) is immersed into the plating solution and is held by, e.g., a “clamshell” substrate holder 609, mounted on a rotatable spindle 611, which allows rotation of clamshell substrate holder 609 together with the substrate 607. A general description of a clamshell-type plating apparatus having aspects suitable for use with this invention is described in detail in U.S. Pat. No. 6,156,167 issued to Patton et al., and U.S. Pat. No. 6,800,187 issued to Reid et al., which are incorporated herein by reference in their entireties. Other types of substrate holders may be used as desired.

An anode 613 is disposed below the substrate 607 within the plating bath 603 and is separated from the substrate region by a membrane 615, preferably an ion selective membrane. For example, Nafion™ cationic exchange membrane (CEM) may be used. The region below the anodic membrane is often referred to as an “anode chamber.” The ion-selective anode membrane 615 allows ionic communication between the anodic and cathodic regions of the plating cell, while preventing the particles generated at the anode from entering the proximity of the substrate and contaminating it. The anode membrane is also useful in redistributing current flow during the plating process and thereby improving the plating uniformity. Detailed descriptions of suitable anodic membranes are provided in U.S. Pat. Nos. 6,126,798 and 6,569,299 issued to Reid et al., both incorporated herein by reference in their entireties. Ion exchange membranes, such as cationic exchange membranes, are especially suitable for these applications. These membranes are typically made of ionomeric materials, such as perfluorinated co-polymers containing sulfonic groups (e.g. Nafion™), sulfonated polyimides, and other materials known to those of skill in the art to be suitable for cation exchange. Selected examples of suitable Nafion™ membranes include N324 and N424 membranes available from Dupont de Nemours Co.

During plating the ions from the plating solution are deposited on the substrate. The metal ions must diffuse through the diffusion boundary layer. A typical way to assist the diffusion is through convection flow of the electroplating solution provided by the pump 617. Additionally, a vibration agitation or sonic agitation member may be used as well as substrate rotation. For example, a vibration transducer 608 may be attached to the clamshell substrate holder 609.

The plating solution is continuously provided to plating bath 603 by the pump 617. Generally, the plating solution flows upwards through an anode membrane 615 and a diffuser plate 619 to the center of substrate 607 and then radially outward and across substrate 607. The plating solution also may be provided into the anodic region of the bath from the side of the plating bath 603. The plating solution then overflows plating bath 603 to an overflow reservoir 621. The plating solution is then filtered (not shown) and returned to pump 617 completing the recirculation of the plating solution. In certain configurations of the plating cell, a distinct electrolyte is circulated through the portion of the plating cell in which the anode is contained while mixing with the main plating solution is prevented using sparingly permeable membranes or ion selective membranes.

A reference electrode 631 is located on the outside of the plating bath 603 in a separate chamber 633, which chamber is replenished by overflow from the main plating bath 603. Alternatively, in some embodiments the reference electrode is positioned as close to the substrate surface as possible, and the reference electrode chamber is connected via a capillary tube or by another method, to the side of the substrate or directly under the substrate. In some of the preferred embodiments, the apparatus further includes contact sense leads that connect to the substrate periphery and which are configured to sense the potential of the metal seed layer at the periphery of the substrate but do not carry any current to the substrate.

A reference electrode 631 is typically employed when electroplating at a controlled potential is desired. The reference electrode 631 may be one of a variety of commonly used types such as mercury/mercury sulfate, silver chloride, saturated calomel, or copper metal. A contact sense lead in direct contact with the substrate 607 may be used in some embodiments, in addition to the reference electrode, for more accurate potential measurement (not shown).

A DC power supply 635 can be used to control current flow to the substrate 607. The power supply 635 has a negative output lead 639 electrically connected to substrate 607 through one or more slip rings, brushes and contacts (not shown). The positive output lead 641 of power supply 635 is electrically connected to an anode 613 located in plating bath 603. The power supply 635, a reference electrode 631, and a contact sense lead (not shown) can be connected to a system controller 647, which allows, among other functions, modulation of current and potential provided to the elements of electroplating cell. For example, the controller may allow electroplating in potential-controlled and current-controlled regimes. The controller may include program instructions specifying current and voltage levels that need to be applied to various elements of the plating cell, as well as times at which these levels need to be changed. When forward current is applied, the power supply 635 biases the substrate 607 to have a negative potential relative to anode 613. This causes an electrical current to flow from anode 613 to the substrate 607, and an electrochemical reduction (e.g. Cu²⁺2 e⁻=Cu⁰) occurs on the substrate surface (the cathode), which results in the deposition of the electrically conductive layer (e.g. copper) on the surfaces of the substrate. An inert anode 614 may be installed below the substrate 607 within the plating bath 603 and separated from the substrate region by the membrane 615.

The apparatus may also include a heater 645 for maintaining the temperature of the plating solution at a specific level. The plating solution may be used to transfer the heat to the other elements of the plating bath. For example, when a substrate 607 is loaded into the plating bath the heater 645 and the pump 617 may be turned on to circulate the plating solution through the electroplating apparatus 601, until the temperature throughout the apparatus becomes substantially uniform. In one embodiment the heater is connected to the system controller 647. The system controller 647 may be connected to a thermocouple to receive feedback of the plating solution temperature within the electroplating apparatus and determine the need for additional heating.

The controller will typically include one or more memory devices and one or more processors. The processor may include a CPU or computer, analog and/or digital input/output connections, stepper motor controller boards, etc. In certain embodiments, the controller controls all of the activities of the electroplating apparatus. Non-transitory machine-readable media containing instructions for controlling process operations in accordance with the present embodiments may be coupled to the system controller.

Typically there will be a user interface associated with controller 647. The user interface may include a display screen, graphical software displays of the apparatus and/or process conditions, and user input devices such as pointing devices, keyboards, touch screens, microphones, etc. The computer program code for controlling electroplating processes can be written in any conventional computer readable programming language: for example, assembly language, C, C++, Pascal, Fortran or others. Compiled object code or script is executed by the processor to perform the tasks identified in the program. One example of a plating apparatus that may be used according to the embodiments herein is the Lam Research Sabre tool. Electrodeposition can be performed in components that form a larger electrodeposition apparatus.

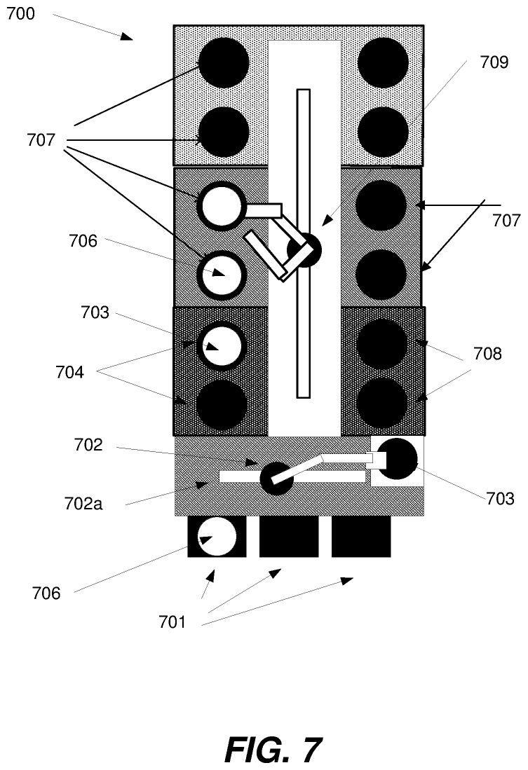

FIG. 7 illustrates electrodeposition apparatus 700 having a set of electroplating cells 707, each containing an electroplating bath, in a paired or multiple “duet” configuration. In addition to electroplating per se, the electrodeposition apparatus 700 may perform a variety of other electroplating related processes and sub-steps, such as spin-rinsing, spin-drying, metal and silicon wet etching, electroless deposition, pre-wetting and pre-chemical treating, reducing, annealing, electro-etching and/or electropolishing, photoresist stripping, and surface pre-activation, for example. The electrodeposition apparatus 700 is shown schematically looking top down in FIG. 7, and only a single level or “floor” is revealed in the figure, but it is to be readily understood by one having ordinary skill in the art that such an apparatus, e.g., the Lam Sabre™ 3D tool, can have two or more levels “stacked” on top of each other, each potentially having identical or different types of processing stations.

Referring once again to FIG. 7, the substrates 706 that are to be electroplated are generally fed to the electrodeposition apparatus 700 through a front end loading FOUP 701 and, in this example, are brought from the FOUP to the main substrate processing area of the electrodeposition apparatus 700 via a front-end robot 702 that can retract and move a substrate 706 driven by a spindle 703 in multiple dimensions from one station to another of the accessible stations—two front-end accessible stations 704 and also two front-end accessible stations 708 are shown in this example. The front-end accessible stations 704 and 708 may include, for example, pre-treatment stations, and spin rinse drying (SRD) stations. Lateral movement from side-to-side of the front-end robot 702 is accomplished utilizing robot track 702a. Each of the substrates 706 may be held by a cup/cone assembly (not shown) driven by a spindle 703 connected to a motor (not shown), and the motor may be attached to a mounting bracket 709. Also shown in this example are the four “duets” of electroplating cells 707, for a total of eight electroplating cells 707. A system controller (not shown) may be coupled to the electrodeposition apparatus 700 to control some or all of the properties of the electrodeposition apparatus 700. The system controller may be programmed or otherwise configured to execute instructions according to processes described earlier herein.

A similar apparatus may be used for electroless deposition, though certain elements may be omitted as understood by those of ordinary skill in the art.

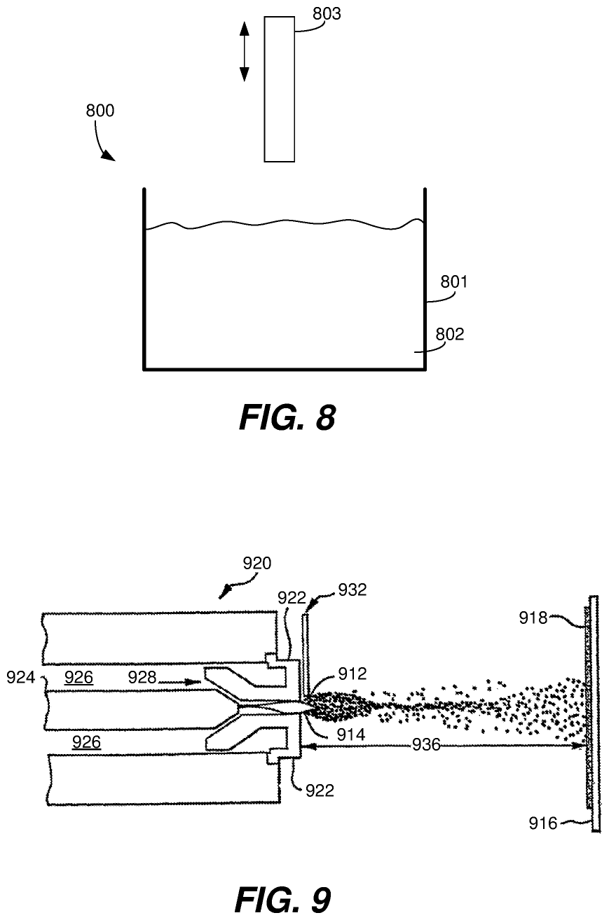

FIG. 8 presents a simplified view of a dip coating apparatus 800 that may be used to coat the heater in some embodiments. The dip coating apparatus 800 includes vessel 801 and substrate support 803. During operation, dip coating solution 802 is provided to vessel 801, and a substrate (e.g., the heater being coated, not shown) is positioned on the substrate support 803. The substrate and substrate support 803 are lowered such that the substrate is immersed in the dip coating solution 802.

The dip coating process may be controlled by a controller, described further below. For instance, the controller may be configured to control the speed at which the substrate support is lowered and/or raised. In some embodiments, the dip coating apparatus 800 may further include plumbing and associated hardware for providing the dip coating solution 802 to and/or from the vessel 801, similar to the plumbing used in the electroplating apparatus 601 of FIG. 6. In such cases, the controller may be configured to control the introduction and removal of the dip coating solution 802 from the vessel 801.

FIG. 9 illustrates a typical plasma spraying process, highlighting relevant portions of the plasma spraying apparatus. As mentioned above, plasma spraying is one type of thermal spraying. The coating material, often in the form of a powder 912, is injected into a high temperature plasma flame 914 usually via an external powder port 932. The powder is rapidly heated and accelerated to a high velocity. The hot material impacts on the substrate surface 916 (e.g., the surface of the heater being coated) and rapidly cools to form a coating 918.

The plasma spray gun 920 comprises an anode 922 and a cathode 924, both of which are cooled (e.g., by water or other heat transfer fluid). Plasma gas 926 (e.g., argon, nitrogen, hydrogen, helium) flows around the cathode in the direction generally indicated by arrow 928 and through a constricting nozzle of the anode. The plasma is initiated by a high voltage discharge, which causes localized ionization and a conductive path for a DC arc to form between the cathode 924 and the anode 922. Resistance heating from the arc causes the gas to form a plasma. The plasma exits the anode nozzle portion as a free or neutral plasma flame (e.g., plasma that does not carry electric current). When the plasma is stabilized and ready for spraying, the electric arc extends down the nozzle. The powder 912 is so rapidly heated and accelerated that the spray distance 936 between the nozzle tip and the substrate surface can be on the order of 125 to 150 mm. Plasma sprayed coatings are produced by molten or heat-softened particles impacting on the substrate surface 916. Various processing conditions related to the plasma spraying process may be controlled by a controller (not shown), as further discussed below. The controller may be configured to control various aspects of the spraying process, including but not limited to, substrate positioning, temperature, pressure, flow rate, power, etc. In a similar embodiment where plasma is not used, the hardware for producing plasma may be swapped with other hardware configured to heat the coating material.

### System Controller

In some implementations, a controller is part of a system, which may be part of the above-described examples. Such systems can comprise semiconductor processing equipment, including a processing tool or tools, chamber or chambers, a platform or platforms for processing, and/or specific processing components (a substrate pedestal, a gas flow system, etc.). These systems may be integrated with electronics for controlling their operation before, during, and after processing of a semiconductor wafer or other substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of fabricating a platen for use in a semiconductor processing apparatus, the method comprising:
depositing or otherwise forming a coating on a heater to form a coated heater, wherein the heater comprises a metal wire on which the coating is formed;
placing the coated heater in powder;
consolidating the powder into a cohesive mass to form a powder-based composite; and
sintering the powder-based composite to form the platen, wherein the platen comprises the heater embedded in sintered ceramic material.

2. The method of claim 1, wherein the coating is deposited on the heater using a technique selected from the group consisting of atomic layer deposition, chemical vapor deposition, electroplating, electroless plating, dip coating, thermal spraying or plasma spraying, and physical vapor deposition.

3. The method of claim 1, wherein the coating is deposited to a thickness of at least about 5 angstroms.

4. The method of claim 1, wherein the coating comprises a metal, metal oxide, an elemental metal, a metal nitride, or an intermetallic compound.

5. (canceled)

6. A platen for use in a semiconductor processing apparatus, the platen comprising:
a coated heater comprising a metal wire with a coating thereon; and
a sintered ceramic material, wherein the coated heater is embedded in the sintered ceramic material.

7. (canceled)

8. A powder-based composite for use as a platen in a semiconductor processing apparatus, the powder-based composite comprising:
a coated heater comprising a metal wire with a coating thereon; and
an unsintered ceramic material, wherein the coated heater is embedded in the unsintered ceramic material.

9. The powder-based composite of claim 8, wherein the coating has a thickness of at least about 5 angstroms.

10. The powder-based composite of claim 8, wherein the coating comprises a metal.

11. The method of claim 1, wherein the coating comprises two or more layers having different compositions.

12. The method of claim 1, wherein depositing or otherwise forming the coating on the coated heater comprises:
depositing alternating layers of aluminum oxide and yttrium oxide on the coated heater through atomic layer deposition.

13. The platen of claim 6, wherein the coating has a thickness of at least about 5 angstroms.

14. The platen of claim 6, wherein the metal wire has a diameter between about 0.002-0.05 inches.

15. The platen of claim 6, wherein the coating comprises a metal.

16. The platen of claim 6, wherein the coating comprises a metal oxide.

17. The platen of claim 6, wherein the coating is an elemental metal.

18. The platen of claim 6, wherein the coating comprises boron nitride.

19. The powder-based composite of claim 8, wherein the coating comprises a metal oxide.

20. The powder-based composite of claim 8, wherein the coating comprises an elemental metal.

21. The powder-based composite of claim 8, wherein the coating is a sacrificial coating comprising a sacrificial material, and wherein carbon- and/or oxygen-containing components present during a sintering operation are more reactive with the sacrificial material than they are with the metal wire.

22. The powder-based composite of claim 8, wherein the coating is a barrier coating comprising a barrier material, and wherein carbon- and/or oxygen-containing components present during a sintering operation are less reactive with the barrier material than they are with the metal wire of the coated heater.
